(19) United States
(12) Patent Application Publication
(10) Pub. No.: US 2024/0072071 A1
(43) Pub. Date: Feb. 29, 2024

(54) DISPLAY PANEL, DETECTION DEVICE THEREFOR, AND DISPLAY DEVICE

(71) Applicant: Tianma Advanced Display Technology Institute (Xiamen) Co.,Ltd., Xiamen (CN)

(72) Inventors: Zhenyu JIA, Xiamen (CN); Chenglong YANG, Xiamen (CN); Kerui XI, Xiamen (CN); Tianyi WU, Xiamen (CN); Xiaoxiang HE, Xiamen (CN); Ping AN, Xiamen (CN); Yingteng ZHAI, Xiamen (CN); Liwei ZHANG, Xiamen (CN); Yukun HUANG, Xiamen (CN); Aowen LI, Xiamen (CN)

(73) Assignee: Tianma Advanced Display Technology Institute (Xiamen) Co.,Ltd., Xiamen (CN)

(21) Appl. No.: 18/501,245

(22) Filed: Nov. 3, 2023

(30) Foreign Application Priority Data
Jun. 30, 2023 (CN) 202310797761.3

(51) Int. Cl. H01L 27/12; H01L 23/544; H01L 25/16

(52) U.S. Cl. CPC H01L 27/124; H01L 23/544; H01L 25/167; H01L 27/1255; H01L 2223/54426

(57) ABSTRACT

Provided are a display panel, a detection device therefor, and a display device. In an embodiment, the display panel includes an array layer, along a thickness direction of the display panel, the array layer including first and second conductive layers, and at least an insulating layer being located between the first and second conductive layers; a light-emitting element located at a side of the array layer facing a light-exiting surface of the display panel; and a first through-hole. In an embodiment, the first and second conductive layers are connected to each other through the first through-hole, and at least one first through-hole is reused as an alignment connection hole; and/or, along the thickness direction of the display panel, orthographic projections of at least two first through-holes onto a plane of the light-exiting surface of the display panel have different shapes.

### CROSS-REFERENCE TO RELATED APPLICATIONS

The present application claims priority to Chinese Patent Application No. 202310797761.3, filed on Jun. 30, 2023, the content of which is incorporated herein by reference in its entirety.

### TECHNICAL FIELD

The present disclosure relates to the technical field of display, and in particular to a display panel, a detection device therefor, and a display device.

### BACKGROUND

Improving alignment precision of display panels having a high pixel density (that is, PPI, pixels per inch) is an urgent issue that needs to be addressed.

### SUMMARY

In view of this and related challenges, the present disclosure provides a display panel, a detection device therefor, and a display device, to address the issue of the lack of region-specific alignment marks in a display region of a high-PPI display panel.

In an aspect, the present disclosure provides a display panel, including: an array layer, along a thickness direction of the display panel, the array layer including at least a first conductive layer and a second conductive layer, and at least an insulating layer being located between the first conductive layer and the second conductive layer; a light-emitting element located at a side of the array layer facing a light-exiting surface of the display panel; and at least one first through-hole. In an embodiment, the first conductive layer and the second conductive layer are connected to each other through the at least one first through-hole, and at least one of the at least one first through-hole is reused as an alignment connection hole; and/or, along the thickness direction of the display panel, orthographic projections of at least two of the at least one first through-hole onto a plane of the light-exiting surface of the display panel have different shapes.

In another aspect, the present disclosure provides a display device including a display panel, including: an array layer, along a thickness direction of the display panel, the array layer including at least a first conductive layer and a second conductive layer, and at least an insulating layer being located between the first conductive layer and the second conductive layer; a light-emitting element located at a side of the array layer facing a light-exiting surface of the display panel; and at least one first through-hole. In an embodiment, the first conductive layer and the second conductive layer are connected to each other through the at least one first through-hole, and at least one of the at least one first through-hole is reused as an alignment connection hole; and/or, along the thickness direction of the display panel, orthographic projections of at least two of the at least one first through-hole onto a plane of the light-exiting surface of the display panel have different shapes.

In another aspect, the present disclosure provides a detection device for a display panel. In an embodiment, the display panel includes: an array layer, along a thickness direction of the display panel, the array layer including at least a first conductive layer and a second conductive layer, and at least an insulating layer being located between the first conductive layer and the second conductive layer; a light-emitting element located at a side of the array layer facing a light-exiting surface of the display panel; and at least one first through-hole. In an embodiment, the first conductive layer and the second conductive layer are connected to each other through the at least one first through-hole, and at least one of the at least one first through-hole is reused as an alignment connection hole; and/or, along the thickness direction of the display panel, orthographic projections of at least two of the at least one first through-hole onto a plane of the light-exiting surface of the display panel have different shapes. In an embodiment, the detection device further includes a recognition device located at a side of a light-exiting surface of the display panel, and the recognition device is configured to photograph the display panel to recognize the alignment connection hole in the display panel.

### BRIEF DESCRIPTION OF DRAWINGS

The accompanying drawings, which are incorporated in and constitute a part of the specification, illustrate embodiments of the present disclosure and together with the description, serve to explain the principles of the present disclosure.

FIG. 1 is a schematic diagram of a display panel according to an embodiment of the present disclosure;

FIG. 2 is a cross-sectional view taken along AA′ in FIG. 1 according to an embodiment of the present disclosure;

FIG. 3 is a top view of first through-holes according to an embodiment of the present disclosure;

FIG. 4 is another cross-sectional view taken along AA′ in FIG. 1 according to an embodiment of the present disclosure;

FIG. 5 is another cross-sectional view taken along AA′ in FIG. 1 according to an embodiment of the present disclosure;

FIG. 6 is another cross-sectional view taken along AA′ in FIG. 1 according to an embodiment of the present disclosure;

FIG. 7 is another cross-sectional view taken along AA′ in FIG. 1 according to an embodiment of the present disclosure;

FIG. 8 is another cross-sectional view taken along AA′ in FIG. 1 according to an embodiment of the present disclosure;

FIG. 9 is another cross-sectional view taken along AA′ in FIG. 1 according to an embodiment of the present disclosure;

FIG. 10 is another cross-sectional view taken along AA′ in FIG. 1 according to an embodiment of the present disclosure;

FIG. 11 is another cross-sectional view taken along AA′ in FIG. 1 according to an embodiment of the present disclosure;

FIG. 12 is a top view of first through-holes and second through-holes according to an embodiment of the present disclosure;

FIG. 13 is another cross-sectional view taken along AA′ in FIG. 1 according to an embodiment of the present disclosure;

FIG. 14 is another cross-sectional view taken along AA′ in FIG. 1 according to an embodiment of the present disclosure;

FIG. 15 is another top view of first through-holes according to an embodiment of the present disclosure;

FIG. 16 is another top view of first through-holes according to an embodiment of the present disclosure;

FIG. 17 is a schematic diagram of a detection device of a display panel according to an embodiment of the present disclosure; and

FIG. 18 is a schematic diagram of a display device according to an embodiment of the present disclosure.

### DESCRIPTION OF EMBODIMENTS

The exemplary embodiments of the present disclosure are described below with reference to the drawings. It should be noted that unless otherwise specified, the relative arrangement, numerical expressions, and numerical values of components and steps set forth in these embodiments do not limit the scope of the present disclosure.

The following description of at least one exemplary example is merely illustrative, and not intended to limit the present disclosure and application or use thereof in any way.

The technologies, methods, and devices known to those of ordinary skill in the art may not be discussed in detail, but where appropriate, the technologies, methods, and devices should be regarded as part of the specification.

In all examples shown and discussed herein, any specific value should be interpreted as merely exemplary, rather than restrictive. Therefore, other examples of the exemplary embodiments may have different values.

It should be noted that similar reference numerals and letters represent similar items in the drawings below. Therefore, once an item is defined in one drawing, it does not need to be further discussed in subsequent drawings.

The mini LED and micro LED high-PPI display products in the related art have pixel units that are mostly in a non-transparent state. This means that an entire array layer of the display panel corresponding to the pixel units is filled with transistors and wiring. As a result, the high-PPI mini LED and micro LED display panels are limited by the available space in the pixel unit display region, making it difficult to add alignment marks in the display region of the display panel. Generally, a large number of alignment marks for transfer are arranged in a non-display region of the display panel. This hinders further enlargement of the display region of high-PPI displays, which is not conducive to the demand for narrow bezel design of the display device. Therefore, it needs to provide a technical solution that allows for the placement of alignment marks within the display region of a high-PPI display panel.

In view of this, the present disclosure provides a display panel, a detection device therefor, and a display device, to address the issue that there is little to no space in a display region of a high-PPI display panel for the placement of alignment marks.

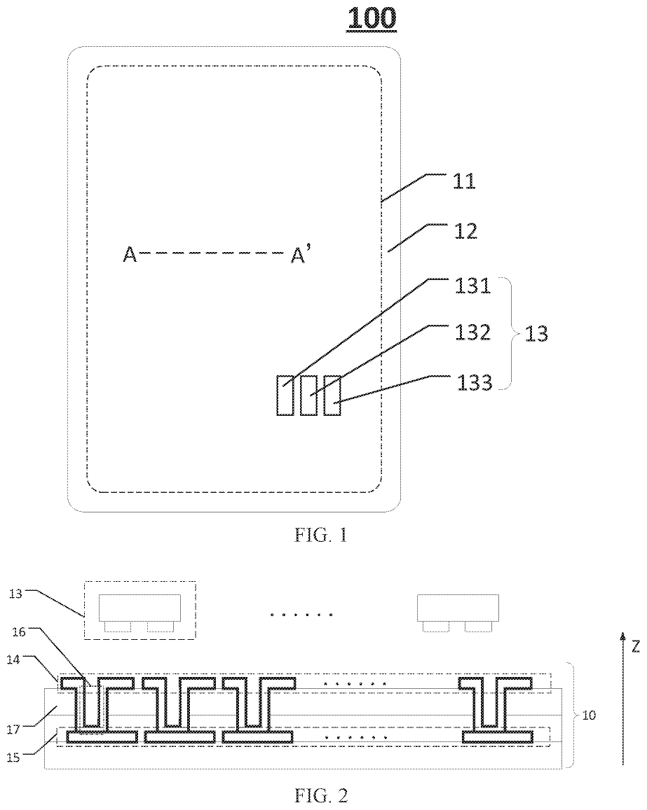

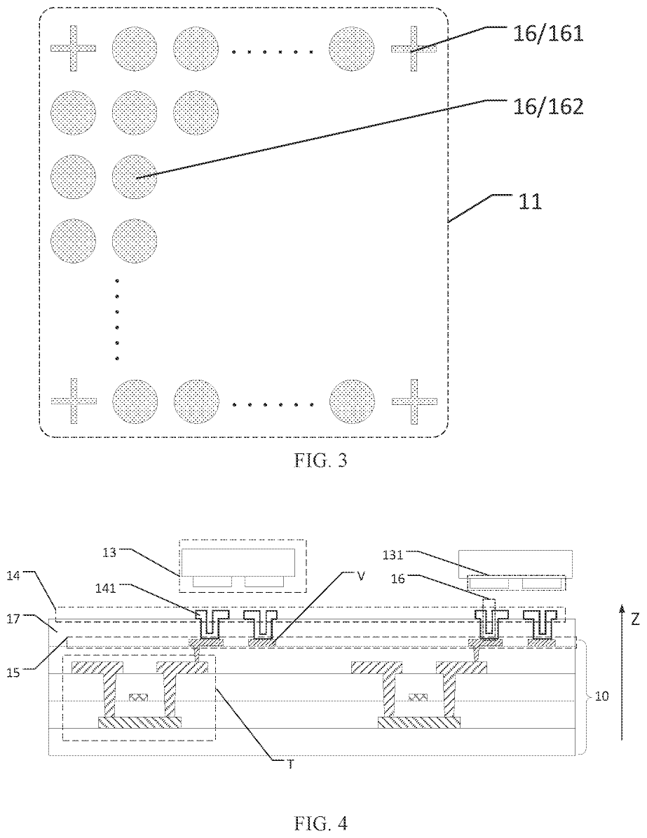

FIG. 1 is a schematic diagram of a display panel according to an embodiment of the present disclosure; FIG. 2 is a cross-sectional view taken along AA′ in FIG. 1 according to an embodiment of the present disclosure; and FIG. 3 is a top view of first through-holes according to an embodiment of the present disclosure. Referring to FIG. 1 to FIG. 3, the present disclosure provides a display panel 100, including an array layer 10, a light-emitting element 13, and at least one first through-hole 16.

The light-emitting element 13 is located at a side of the array layer 10 facing a light-exiting surface of the display panel 100.

Along a thickness direction Z of the display panel 100, the array layer 10 includes at least a first conductive layer 14 and a second conductive layer 15, and at least an insulating layer 17 is located between the first conductive layer 14 and the second conductive layer 15.

The first conductive layer 14 and the second conductive layer 15 are connected to each other through the first through-hole 16.

At least one of the at least one first through-hole 16 is reused as an alignment connection hole 161; and/or, the at least one first through-hole 16 includes multiple first through-holes 16, and along the thickness direction Z of the display panel 100, orthographic projections of at least two first through-holes 16 of the multiple first through-holes 16 onto a plane of the light-exiting surface of the display panel 100 have different shapes.

In an example, an embodiment of the present disclosure provides a display panel 100. The display panel 100 includes an array layer 10 and light-emitting elements 13 located at a side of the array layer 10 facing a light-exiting surface of the display panel 100. Along a thickness direction Z of the display panel 100, the array layer 10 includes at least a first conductive layer 14 and a second conductive layer 15, and at least an insulating layer 17 is located between the first conductive layer 14 and the second conductive layer 15. To achieve electrical connection for at least some of the circuits in the display panel 100, at least one first through-hole 16 is provided to achieve electrical connection between the first conductive layer 14 and the second conductive layer 15. Based on this, an embodiment of the present disclosure provides an optional implementation where at least one of the at least one first through-hole 16 is reused as an alignment connection hole 161. Alternatively, along the thickness direction Z of the display panel 100, the at least one first through-hole 16 includes multiple first through-holes 16, and orthographic projections of at least two of the multiple first through-holes 16 onto the light-exiting surface of the display panel 100 have different shapes; and at least one first through-hole 16, an orthographic projection of which has a relatively different shape, is reused as an alignment connection hole 161.

It can be seen that, in the present disclosure, at least one first through-hole 16 that has already been formed in an original circuit structure of the display panel 100 is directly reused as the alignment mark (the alignment connection hole 161). In this way, it is unnecessary to reduce the PPI of the display panel 100 to create space for the alignment marks, thereby allowing for placement of the alignment marks while maintaining a good display effect of the display panel 100. Additionally, by reusing at least one first through-hole 16 originally existing in the array layer 10 as the alignment connection hole 161, a manufacturing process of the display panel 100 is not increased. Furthermore, the alignment mark is arranged within the display region 11 of the display panel 100, thereby not enlarging an area of the display region 11 of the display panel 100 or reducing the quantity of pixel units to provide the alignment connection hole 161. This avoids a decrease in the PPI of the display panel 100; moreover, the alignment mark helps to improve the alignment effect during the module assembly, and enhance the assembly precision between modules.

It should be additionally noted that along the thickness direction Z of the display panel 100, the depths of the first through-holes 16 in the display panel 100 can be the same. That is, the alignment connection hole 161 and the regular first through-hole 16 can have a same depth in the display panel 100, avoiding an increase in the thickness of the film layer of the display panel 100. To differentiate between the alignment connection hole 161 and the regular first through-hole 16, orthographic projections of the alignment connection hole 161 and the regular first through-hole 16 onto the plane of the display panel 100 have different shapes. However, the present disclosure is not limited thereto, and the depths of the alignment connection hole 161 and the regular first through-hole 16 along the thickness direction of the display panel 100 may also be different as required.

FIG. 4 is another cross-sectional view taken along AA′ in FIG. 1 according to an embodiment of the present disclosure. Referring to FIG. 1 to FIG. 4, in an implementation manner, the array layer 10 further includes a connection electrode 141 electrically connected to the light-emitting element 13. The connection electrode 141 reuses the first conductive layer 14.

The first conductive layer 14 is located at a side of the second conductive layer 15 facing the light-emitting element 13.

In an example, when the display panel 100 includes the first conductive layer 14 and the second conductive layer 15, the first conductive layer 14 can be arranged at a side of the second conductive layer 15 facing the light-emitting element 13. Based on this, an embodiment of the present disclosure further provides an optional implementation where the array layer 10 further includes connection electrode 141 electrically connected to the light-emitting element 13. The connection electrodes 141 are used to establish electrical connection from a transistor unit T and a fixed potential V in the array layer 10 to the electrodes 131 of the light-emitting element 13. Therefore, the connection electrodes 141 need to be electrically connected to the transistor unit T and the fixed potential V that are arranged at a side away from the light-emitting element 13, and in an example, the connection electrodes 141 need to be electrically connected to the corresponding transistor unit T and the fixed potential V through through-holes formed along the thickness direction of the display panel 100. In this case, the connection electrodes 141 can be fabricated by reusing the first conductive layer 14, while the source-drain electrode of the transistor unit T and the fixed potential V can be fabricated by reusing the second conductive layer 15. The through-holes formed between the connection electrode 141 and the source-drain electrode of the transistor unit T and between the connection electrode 141 and the fixed potential V are the first through-holes 16. At least one of the through-holes formed between the connection electrodes 141 and the source-drain electrode of the transistor units T and between the connection electrodes 141 and the fixed potential V can be reused as the alignment connection hole 161, so that there is no need to reduce the PPI of the display panel 100 to create available space for the alignment mark. This allows for the placement of the alignment mark while maintaining a good display effect of the display panel 100. Furthermore, in this embodiment of the present disclosure, by reusing at least one of the first through-holes 16 originally existing in the array layer 10 as the alignment connection hole 161, the manufacturing process of the display panel 100 is not increased. Moreover, by arranging the alignment mark in the display region 11 of the display panel 100, there is no need to enlarge an area of the display region 11 of the display panel 100 or reduce the quantity of pixel units to arrange the alignment connection hole 161. This avoids a decrease in the PPI of the display panel 100. Additionally, the alignment mark helps to improve the alignment effect during module assembly and enhance the assembly precision between modules.

In the embodiment shown in FIG. 4, the fixed potential V can be fabricated by reusing the second conductive layer 15, but the present disclosure is not limited thereto.

Additionally, it should be noted that the connection electrode 141 electrically connected to the light-emitting element 13 can be a solder pad. The solder pad is located at a side of the array layer 10 closest to the light-emitting element 13. When the light-emitting element 13 is bonded to the array layer 10, a eutectic layer or a bonding material can be further provided between the solder pad and the light-emitting element 13 to enhance the electrical connection between the light-emitting element 13 and the solder pad. This ensures the effective transmission of electrical signals from the array layer 10 to the light-emitting element 13, to enable the circuit structure in the array layer 10 to control a light-emitting state and a non-light-emitting state of the light-emitting element 13, thus ensuring a good display effect of the display panel 100.

FIG. 5 is another cross-sectional view taken along AA′ in FIG. 1 according to an embodiment of the present disclosure. Referring to FIG. 1 to FIG. 3 and FIG. 5, in an embodiment, the array layer 10 further includes a capacitor 20.

One electrode plate of the capacitor 20 reuses the first conductive layer 14.

The first conductive layer 14 is located at a side of the second conductive layer 15 facing the light-emitting element 13.

In an example, when the display panel 100 includes the first conductive layer 14 and the second conductive layer 15, the first conductive layer 14 can be arranged at a side of the second conductive layer 15 facing the light-emitting element 13. Based on this, an embodiment of the present disclosure further provides an optional implementation where the array layer 10 further includes a capacitor 20. The capacitor 20 includes at least two electrode plates (21 and 22) that are arranged opposite to each other. One of the electrode plates (such as 21) of the capacitor 20 can be fabricated by reusing the first conductive layer 14. In this case, when the electrode plate (21) is connected to a film layer structure (such as 24) at a side away from the light-emitting element 13, a through-hole formed between the electrode plate and the underlying film layer structure is the first through-hole 16. At least one of the first through-holes 16 that connect the electrode plate of the capacitor 20 and the corresponding film layer can be reused as the alignment connection hole 161. In this way, it is unnecessary to reduce the PPI of the display panel 100 to create available space for the alignment mark, allowing for placement of the alignment mark while maintaining a good display effect of the display panel 100. Furthermore, by reusing at least one of the first through-holes 16 originally existing in the array layer 10 as the alignment connection hole 161, the present disclosure does not increase the manufacturing process of the display panel 100. Additionally, by setting the alignment mark within the display region 11 of the display panel 100, there is no need to enlarge an area of the display region 11 of the display panel 100 or reduce the quantity of pixel units to provide the alignment connection hole 161. This avoids a decrease in the PPI of the display panel 100. Moreover, the alignment mark helps to improve the alignment precision during module assembly and enhance the assembly precision between modules.

In addition, it should be noted that along the thickness direction Z of the display panel 100, an area of an orthographic projection of the electrode plate of the capacitor 20 onto the light-exiting surface of the display panel 100 is larger than an area of an orthographic projection of the corresponding first through-hole 16 onto the light-exiting surface of the display panel 100. By forming the alignment connection hole 161 at a side, which is away from the light-emitting element 13, of the electrode plate of the capacitor 20, the electrode plate of the capacitor 20 having a larger area can cover the first through-hole 16 more effectively. Furthermore, an alignment pattern formed by the first through-hole 16 reused as the alignment mark in combination with the electrode plate of the capacitor 20 becomes more prominent, thereby further enhancing the alignment precision between modules.

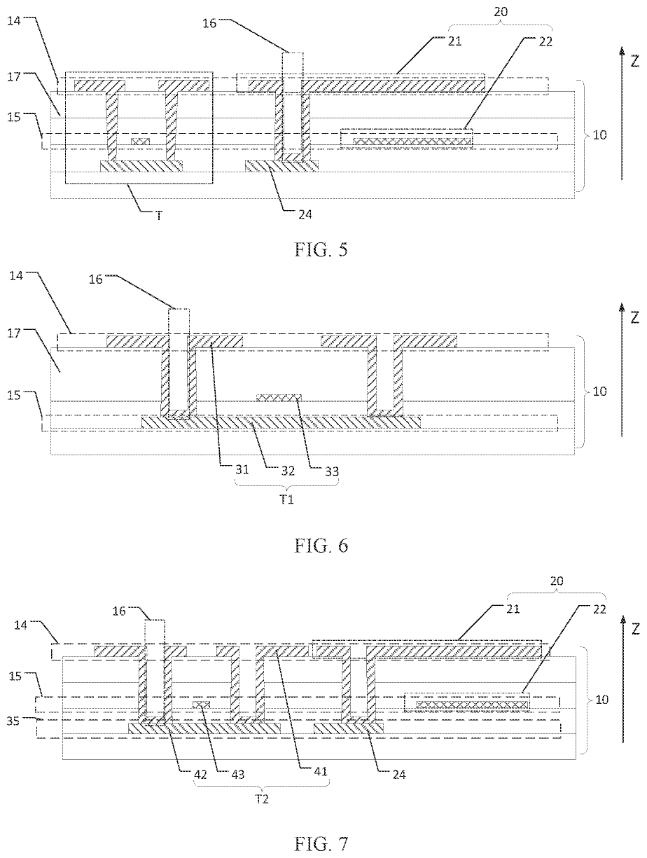

FIG. 6 is another cross-sectional view taken along AA′ in FIG. 1 according to an embodiment of the present disclosure. Referring to FIG. 1 to FIG. 3 and FIG. 6, in an embodiment, the array layer 10 further includes a first transistor T1. A source-drain layer 31 of the first transistor T1 reuses the first conductive layer 14.

The first conductive layer 14 is located at a side of the second conductive layer 15 facing the light-emitting element 13.

In an example, when the display panel 100 includes the first conductive layer 14 and the second conductive layer 15, the first conductive layer 14 can be arranged at a side of the second conductive layer 15 facing the light-emitting element 13. Based on this, an embodiment of the present disclosure further provides an optional implementation where the array layer 10 further includes a first transistor T1. The first transistor T1 includes a source-drain layer 31. The source-drain layer 31 can be fabricated by reusing the first conductive layer 14. The source-drain layer 31 is connected to an active layer 32 of the first transistor T1 through a through-hole, where the active layer 32 is arranged at a side of the source-drain layer 31 away from the light-emitting element 13. A through-hole formed between the source-drain layer 31 and the active layer 32 is the first through-hole 16. At least one first through-hole 16 that connects the source-drain layer 31 and the active layer 32 can be reused as the alignment connection hole 161. It is unnecessary to reduce the PPI of the display panel 100 to create available space for the alignment mark, allowing for the setting of the alignment mark while maintaining a good display effect of the display panel 100. Furthermore, by reusing at least one of the first through-holes 16 originally existing in the array layer 10 as the alignment connection hole 161, the present disclosure does not increase the manufacturing process of the display panel 100. Additionally, by setting the alignment mark within the display region 11 of the display panel 100, there is no need to enlarge an area of the display region 11 of the display panel 100 or reduce the quantity of pixel units to provide the alignment connection hole 161. This avoids a decrease in the PPI of the display panel 100. Moreover, the alignment mark helps to improve the alignment precision during module assembly and enhance the assembly precision between modules. In addition, the first transistor T1 further includes a gate electrode 33.

It should be additionally noted that the present disclosure does not specifically specify which transistor in the pixel circuit serves as the first transistor T1. The first transistor T1 can be selected based on design requirements.

Referring to FIG. 1 to FIG. 3 and FIG. 5, in an implementation manner, the array layer 10 further includes a capacitor 20.

Along the thickness direction Z of the display panel 100, at least one capacitor 20 includes a first electrode plate 21 and a second electrode plate 22 that are opposite to each other. The first electrode plate 21 is located at a side of the second electrode plate 22 facing the light-emitting element 13.

The first electrode plate 21 reuses the first conductive layer 14.

The first conductive layer 14 is located at a side of the second conductive layer 15 facing the light-emitting element 13.

In an example, when the display panel 100 includes the first conductive layer 14 and the second conductive layer 15, the first conductive layer 14 can be arranged at a side of the second conductive layer 15 facing the light-emitting element 13. Based on this, an embodiment of the present disclosure further provides an optional implementation where the array layer 10 further includes a capacitor 20. The capacitor 20 includes at least a first electrode plate 21 and a second electrode plate 22 that are opposite to each other. The second electrode plate 22 is located at a side of the first electrode plate 21 away from the light-emitting element 13. The first electrode plate 21 of the capacitor 20 can be fabricated by reusing the first conductive layer 14. When the first electrode plate 21 is connected to a film layer structure 24 at a side away from the light-emitting element 13, a through-hole formed between the first electrode plate 21 and the underlying film layer structure 24 is the first through-hole 16. At least one first through-hole 16 that connects the first electrode plate 21 and the corresponding film layer can be reused as the alignment connection hole 161. It is unnecessary to reduce the PPI of the display panel 100 to create available space for the alignment mark, allowing for the setting of the alignment mark while maintaining a good display effect of the display panel 100. Furthermore, by reusing at least one first through-hole 16 originally existing in the array layer 10 as the alignment connection hole 161, the present disclosure does not increase the manufacturing process of the display panel 100. Additionally, by setting the alignment mark within the display region 11 of the display panel 100, there is no need to enlarge an area of the display region 11 of the display panel 100 or reduce the quantity of pixel units to provide the alignment connection holes 161. This avoids a decrease in the PPI of the display panel 100. Moreover, the alignment mark helps to improve the alignment precision during module assembly and enhance the assembly precision between modules.

FIG. 7 is another cross-sectional view taken along AA′ in FIG. 1 according to an embodiment of the present disclosure. Referring to FIG. 1 to FIG. 3 and FIG. 7, in an implementation manner, the array layer 10 further includes a first active layer 35. Along the thickness direction Z of the display panel 100, the first active layer 35 is located at a side of the second conductive layer 15 away from the first conductive layer 14.

The array layer 10 further includes a second transistor T2. A source-drain layer 41 of the second transistor T2 is arranged in the first conductive layer 14, and an active layer 42 of the second transistor T2 is arranged in the first active layer 35. The second electrode plate 22 is arranged in the second conductive layer 15.

In an example, the array layer 10 of the display panel 100 further includes a first active layer 35. Along the thickness direction Z of the display panel 100, when the first conductive layer 14 is arranged at the side of the second conductive layer 15 facing the light-emitting element 13, the first active layer 35 can be further arranged at a side of the second conductive layer 15 away from the first conductive layer 14. In addition to the capacitor 20, the array layer 10 of the display panel 100 further includes a plurality of transistors, such as a second transistor T2. The second transistor T2 includes a source-drain layer 41 and an active layer 42. The source-drain layer 41 of the second transistor T2 can be fabricated by reusing the first conductive layer 14, and the active layer 42 can be fabricated by reusing the first active layer 35. The first electrode plate 21 of the capacitor 20 is fabricated by reusing the first conductive layer 14, and the second electrode plate 22 of the capacitor 20 is fabricated by reusing the second conductive layer 15. In this case, when the source-drain layer 41 of the second transistor T2 is connected to the active layer 42 of the second transistor T2, a through-hole formed between the source-drain layer 41 and the active layer 42 of the second transistor T2 is the first through-hole 16. At least one first through-hole 16 that connects the source-drain layer 41 and the active layer 42 of the second transistor T2 can be reused as the alignment connection hole 161. It is unnecessary to reduce the PPI of the display panel 100 to create available space for the alignment mark, allowing for the setting of the alignment mark while maintaining a good display effect of the display panel 100. Furthermore, by reusing at least one of the first through-holes 16 originally existing in the array layer 10 as the alignment connection hole 161, the present disclosure does not increase the manufacturing process of the display panel 100. Additionally, by setting the alignment mark within the display region 11 of the display panel 100, there is no need to enlarge an area of the display region 11 of the display panel 100 or reduce the quantity of pixel units to provide the alignment connection holes 161. This avoids a decrease in the PPI of the display panel 100. Moreover, the alignment mark helps to improve the alignment precision during module assembly and enhance the assembly precision between modules.

It should be additionally noted that the present disclosure does not specifically specify which transistor in the pixel circuit serves as the second transistor T2. The second transistor T2 can be selected based on design requirements. The second transistor T2 includes a gate electrode 43 in addition to the source-drain layer 41 and the active layer 42. The gate electrode 43 can be fabricated by reusing the second conductive layer 15, or can be fabricated at a side of the active layer away from the source-drain layer as required. The present disclosure does not specify the specific film layer configuration of the gate electrode, and it can be selected as required.

Additionally, it should be noted that the first electrode plate 21 of the capacitor 20 is fabricated by reusing the first conductive layer 14, and the second electrode plate 22 is fabricated by reusing the second conductive layer 15. The capacitor 20 and the first through-hole 16 (alignment connection hole 161) that is formed at the side of the first electrode plate 21 away from the light-emitting element 13 are both fabricated by reusing the necessary film layer structures in the display panel 100. This does not increase the quantity of film layers in the display panel 100 and helps to ensure the thin design requirements of the display panel 100.

FIG. 8 is another cross-sectional view taken along AA′ in FIG. 1 according to an embodiment of the present disclosure; FIG. 9 is another cross-sectional view taken along AA′ in FIG. 1 according to an embodiment of the present disclosure. It should be additionally noted that, a difference between FIG. 8 and FIG. 9 lies in a different film layer in which the second conductive layer 15 is located. Referring to FIG. 1 to FIG. 3, FIG. 8, and FIG. 9, in an implementation manner, the array layer 10 further includes a capacitor intermediate layer 23, which is located between the first electrode plate 21 and the second electrode plate 22.

Along the thickness direction Z of the display panel 100, the capacitor intermediate layer 23 at least partially overlaps with the first electrode plate 21, and the capacitor intermediate layer 23 also at least partially overlaps with the second electrode plate 22.

The display panel 100 further includes at least one second through-hole 18. The first electrode plate 21 and the capacitor intermediate layer 23 are connected to each other through the second through-hole 18. At least one second through-hole 18 is reused as the alignment connection hole 161.

In an example, the present disclosure further provides an optional implementation where the capacitor 20 includes not only the first electrode plate 21 and the second electrode plate 22 that are opposite to each other, but also a capacitor intermediate layer 23. Along the thickness direction Z of the display panel 100, the capacitor intermediate layer 23 can be arranged between the first electrode plate 21 and the second electrode plate 22. An insulating layer 17 is arranged between the first electrode plate 21 and the capacitor intermediate layer 23, and another insulating layer 17 is arranged between the capacitor intermediate layer 23 and the second electrode plate 22, ensuring the normal functionality of the capacitor 20 in the driving circuit. Furthermore, along the thickness direction Z of the display panel 100, an orthographic projection of the capacitor intermediate layer 23 onto the light-exiting surface of the display panel 100 can partially overlap with an orthographic projection of the first electrode plate 21 onto the light-exiting surface of the display panel 100, and the orthographic projection of the capacitor intermediate layer 23 onto the light-exiting surface of the display panel 100 can partially overlap with an orthographic projection of the second electrode plate 22 onto the light-exiting surface of the display panel 100. The first electrode plate 21 and the second electrode plate 22 can be electrically connected to each other through the first through-hole 16. The first electrode plate 21 and the capacitor intermediate layer 23 can be electrically connected to each other through the second through-hole 18. In this case, not only at least one first through-hole 16 but also at least one second through-hole 18 can be reused as the alignment connection hole 161.

It should be additionally noted that when the display panel 100 includes the first through-hole 16 formed between the first electrode plate 21 and the second electrode plate 22, and the second through-hole 18 formed between the first electrode plate 21 and the capacitor intermediate layer 23, it is possible to selectively reuse at least one first through-hole 16 as the alignment mark according to requirements, or selectively reuse at least one second through-hole 18 as the alignment mark according to requirements, or simultaneously reuse at least one first through-hole 16 and at least one second through-hole 18 as the alignment marks according to requirements, which is not specifically limited in the present disclosure.

The capacitor intermediate layer 23 is arranged between the first electrode plate 21 and the second electrode plate 22. In the related art, the capacitor 20 of the driving circuit often utilizes a sum of the capacitance 20 formed between the first electrode plate 21 and the capacitor intermediate layer 23, the capacitance 20 formed between the second electrode plate 22 and the capacitor intermediate layer 23, and the capacitance 20 formed between the first electrode plate 21 and the second electrode plate 22. Therefore, the formation of the first through-hole 16 and the second through-hole 18 neither increases the quantity of film layers in the display panel 100, nor increases the thickness of the film layers in the display panel 100. This is advantageous for ensuring the thin design requirements of the display panel 100. In addition, by reusing at least one first through-hole 16 formed between the first electrode plate 21 and the second electrode plate 22 as the alignment connection hole 161, and/or reusing at least one second through-hole 18 formed between the first electrode plate 21 and the capacitor intermediate layer 23 as the alignment connection hole 161, it is unnecessary to reduce the PPI of the display panel 100 to create space for the alignment mark, allowing for the placement of the alignment mark while maintaining a good display effect of the display panel 100. Additionally, by reusing at least one first through-hole 16 and/or second through-hole 18 originally existing in the array layer 10 as the alignment connection hole 161, the present disclosure does not increase the manufacturing process of the display panel 100. Furthermore, the alignment mark is arranged within the display region 11 of the display panel 100, which does not require enlarging an area of the display region 11 of the display panel 100 or reducing the quantity of pixel units to provide the alignment connection holes 161. This avoids a decrease in the PPI of the display panel 100. Moreover, the alignment mark helps to improve the alignment effect during the module assembly, and enhance the assembly precision between modules.

It should be additionally noted that the term “second through-hole (18)” mentioned above is just a naming convention for a type of through-hole, and the term “second through-hole” is not limited to a specific through-hole.

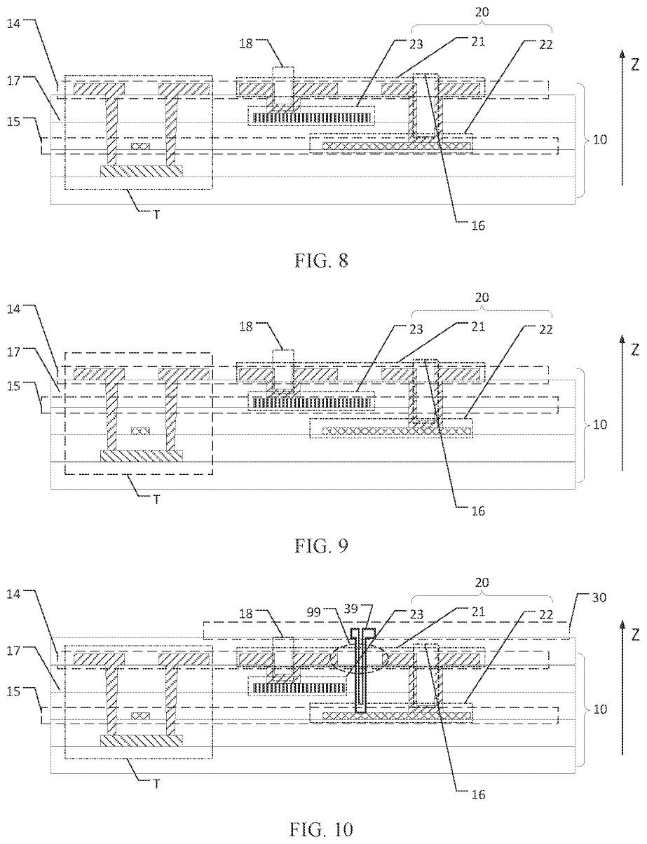

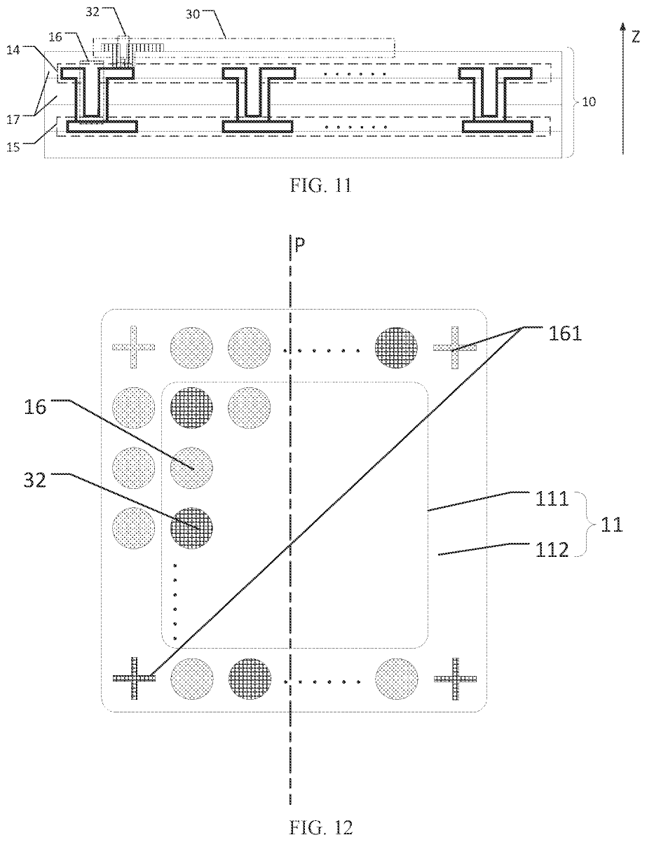

FIG. 10 is another cross-sectional view taken along AA′ in FIG. 1 according to an embodiment of the present disclosure. Referring to FIG. 1 to FIG. 3 and FIG. 10, an embodiment of the present disclosure further provides an optional implementation where, when the capacitor 20 includes the first electrode plate 21 and the second electrode plate 22, the display panel 100 can further include a third conductive layer 30. The third conductive layer 30 is located at a side of the first electrode plate 21 away from the second electrode plate 22. The third conductive layer 30 can be used to set up traces 39. When the traces 39 need to be electrically connected to the second electrode plate 22, the traces 39 can be set up using a cutout region 99 in the first electrode plate 21. The electrical connection between the traces 39 and the second electrode plate 22 can be achieved by utilizing the cutout region 99 of the first electrode plate 21, thereby helping save space compared with a case that the electrical connection with the second electrode plate 22 is achieved by setting the traces 39 outside the capacitor 20.

Furthermore, since the traces 39 and the second electrode plate 22 need to be electrically connected to each other through through-holes, it is also possible to reuse at least one of the through-holes that electrically connect the traces 39 and the second electrode plate 22 in the display panel 100 as the alignment connection hole 161.

Additionally, it should be noted that if the traces located in the third conductive layer 30 need to be electrically connected to other components in the second conductive layer 15 or the first conductive layer 14, through-holes are also required to achieve the electrical connection. Similarly, at least one of these through-holes can be used as the alignment connection hole.

FIG. 11 is another cross-sectional view taken along AA′ in FIG. 1 according to an embodiment of the present disclosure. Referring to FIG. 1, FIG. 3, and FIG. 11, in an implementation manner, the array layer 10 further includes a third conductive layer 30. Along the thickness direction Z of the display panel 100, the first conductive layer 14 is located at a side of the second conductive layer 15 facing the light-emitting element 13. The third conductive layer 30 is located at a side of the first conductive layer 14 away from the second conductive layer 15.

The display panel 100 further includes at least one second through-hole 32. The first conductive layer 14 and the third conductive layer 30 are connected to each other through the second through-hole 32. At least one second through-hole 32 is reused as the alignment connection hole 161.

In an example, the present disclosure further provides an optional implementation where the display panel 100 further includes a third conductive layer 30 in addition to the first conductive layer 14 and the second conductive layer 15. Along the thickness direction Z of the display panel 100, the first conductive layer 14 can be located at a side of the second conductive layer 15 facing the light-emitting element 13, and the third conductive layer 30 can be located at a side of the first conductive layer 14 away from the second conductive layer 15. An insulating layer 17 is arranged between the third conductive layer 30 and the first conductive layer 14. In this case, when the first conductive layer 14 and the second conductive layer 15 are connected to each other through the first through-hole 16, the third conductive layer 30 and the first conductive layer 14 can further be connected to each other through the second through-hole 32. Furthermore, according to requirements, it is possible to selectively reuse at least one first through-hole 16 as the alignment connection hole 161, or selectively reuse at least one second through-hole 32 as the alignment connection hole 161, or simultaneously select at least one first through-hole 16 and at least one second through-hole 32 as the alignment connection holes 161, which is not specifically limited in the present disclosure, and corresponding elections can be made based on the requirements.

For the display panel in the related art, a third conductive layer may be arranged at a side of the first conductive layer away from the second conductive layer, for example, the third conductive layer and the solder pad used for electrical connection with the light-emitting element are arranged in a same layer. Therefore, the formation of the first through-hole 16 and the second through-hole 32 between the first conductive layer 14, the second conductive layer 15, and the third conductive layer 30 neither increases the quantity of film layers of the display panel 100, nor increases the thickness of the film layers of the display panel 100. This is beneficial for ensuring the thin design requirements of the display panel 100. In addition, by reusing at least one first through-hole 16 formed between the first conductive layer 14 and the second conductive layer 15 as the alignment connection hole 161, and/or reusing at least one second through-hole 32 formed between the third conductive layer 30 and the first conductive layer 14 as the alignment connection hole 161, it is unnecessary to reduce the PPI of the display panel 100 to create space for the alignment mark, allowing for the placement of the alignment mark while maintaining a good display effect of the display panel 100. Additionally, in the present disclosure, at least one first through-hole 16 and/or at least one second through-hole 32 originally existing in the array layer 10 is reused as the alignment connection hole 161, and the alignment mark is arranged within the display region 11 of the display panel 100, which does not require enlarging an area of the display region 11 of the display panel 100 or reducing the quantity of pixel units to provide the alignment connection hole 161. This avoids a decrease in the PPI of the display panel 100. Moreover, the alignment mark helps to improve the alignment effect during the module assembly, and enhance the assembly precision between modules.

It should be additionally noted that the term “second through-hole (32)” mentioned above is just a naming convention for a type of through-hole, and the term “second through-hole” is not limited to a specific through-hole.

FIG. 12 is a top view of first through-holes and second through-holes according to an embodiment of the present disclosure. Further referring to FIG. 1, FIG. 3, FIG. 11, and FIG. 12, in an implementation manner, along the thickness direction Z of the display panel 100, an orthographic projection of at least one first through-hole 16 onto the plane of the light-exiting surface of the display panel 100 and an orthographic projection of at least one second through-hole 32 onto the plane of the light-exiting surface of the display panel 100 may have a same shape.

In an example, when the first conductive layer 14 and the second conductive layer 15 are connected to each other through the first through-hole 16, and the third conductive layer 30 and the first conductive layer 14 are connected to each other through the second through-hole 32, an embodiment of the present disclosure further provides an optional embodiment where along the thickness direction Z of the display panel 100, an orthographic projection of at least one first through-hole 16 onto the plane of the light-exiting surface of the display panel 100 and an orthographic projection of at least one second through-hole 32 onto the plane of the light-exiting surface of the display panel 100 have a same shape. For example, the first through-hole 16 and the second through-hole 32 that are reused as the alignment connection holes 161 can have a same shape, so that it facilitates fabricating the alignment connection holes 161 by using a same manufacturing process and allows users to easily recognize the alignment connection holes 161. For example, the first through-hole 16 and the second through-hole 32 that are not reused as the alignment connection hole 161 can have a same shape, so that it also facilitates production using a same manufacturing process to avoid an increase in process complexity, and allows users to easily recognize the alignment connection hole 161 that has a different shape.

It should be additionally noted that the term “second through-hole (32)” mentioned above is just a naming convention for a type of through-hole, and the term “second through-hole” is not limited to a specific through-hole.

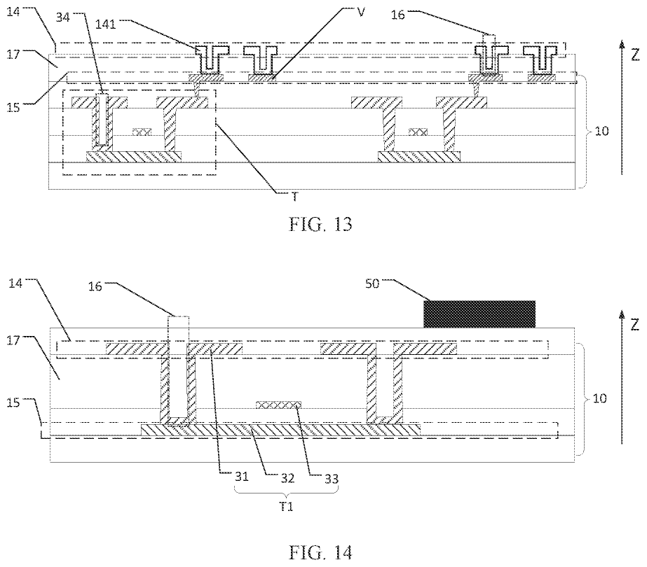

FIG. 13 is another cross-sectional view taken along AA′ in FIG. 1 according to an embodiment of the present disclosure. Referring to FIG. 1 to FIG. 3, and FIG. 13, in an implementation manner, the array layer 100 further includes at least one second through-hole 34. Along the thickness direction Z of the display panel 100, the second through-hole 34 is located at a side of the first through-hole 16 away from the light-emitting element 13.

Along the thickness direction Z of the display panel 100, the second through-hole 34 does not overlap with the alignment connection hole 161.

In an example, when the first conductive layer 14 and the second conductive layer 15 of the display panel 100 are connected to each other through the first through-hole 16, the display panel 100 can further include a second through-hole 34. Along the thickness direction Z of the display panel 100, when the second through-hole 34 is located at a side of the first through-hole 16 away from the light-emitting element 13, the orthographic projection of the second through-hole 34 onto the light-exiting surface of the display panel 100 does not overlap with the orthographic projection of the first through-hole 16, which is reused as the alignment connection hole 161, onto the light-exiting surface of the display panel 100. This avoids the problem that the alignment connection hole 161 is recessed towards the second through-hole 34, thereby preventing any changes in the depth or shape of the originally intended alignment connection hole 161 caused by the placement of the film layers. It also prevents misidentification issues caused by unevenness in the film layer below the alignment connection hole 161, ensuring that the alignment connection hole 161 can be effectively used for recognition and alignment and guaranteeing the alignment connection effect between modules.

It should be additionally noted that the term “second through-hole (34)” mentioned above is just a naming convention for a type of through-hole, and the term “second through-hole 34” is not limited to a specific through-hole.

Referring to FIG. 1 to FIG. 6, in an implementation manner, the light-emitting element 13 includes at least a first color light-emitting element 131.

The array layer 10 further includes a first connection electrode electrically connected to the first color light-emitting element 131, where the first connection electrode reuses the first conductive layer.

And/or, the array layer 10 further includes a first capacitor corresponding to the first color light-emitting element 131, where one electrode plate of the first capacitor reuses the first conductive layer.

And/or, the array layer 10 further includes a third transistor corresponding to the first color light-emitting element 131, where a source-drain layer of the third transistor reuses the first conductive layer.

The first color light-emitting element 131 does not include a green color.

The first conductive layer is located at a side of the second conductive layer 15 facing the light-emitting element 13.

In an example, the light-emitting element 13 in the display panel 100 generally includes at least a red light-emitting element 132, a green light-emitting element 131, and a blue light-emitting element 133, and the human eye is most sensitive to the color emitted by the green light-emitting element 131. Based on this, an embodiment of the present disclosure further provides an optional implementation where the first connection electrode electrically connected to the non-green light-emitting element can be fabricated by reusing the first conductive layer; and/or, one electrode plate of the first capacitor corresponding to the non-green light-emitting element can be fabricated by reusing the first conductive layer; and/or, the source-drain layer of the third transistor corresponding to the non-green light-emitting element can be fabricated by reusing the first conductive layer. Due to the fact that the human eye is most sensitive to the color emitted by the green light-emitting element 131, the alignment connection hole 161 can be arranged in a region corresponding to the non-green light-emitting element, such as the red light-emitting element 132 and/or the blue light-emitting element 133. Even if the alignment connection hole 161 has a slight impact on the display effect in the region corresponding to the red light-emitting element 132 and/or the blue light-emitting element 133, a minor difference in the display effect of the display panel 100 is less noticeable to the human eye as users are less sensitive to the light emitted by the red light-emitting element 132 and the blue light-emitting element 133. This ensures that the users can still observe the display effect of the display panel 100 when the alignment connection hole 161 exists in the display panel 100.

It should be additionally noted that the present disclosure does not specifically specify which transistor in the pixel circuit serves as the third transistor. The third transistor can be selected based on design requirements. For the third transistor, reference can be made to T2 in FIG. 7.

Referring to FIG. 1 to FIG. 3, in an implementation manner, at least one first connection hole 162 can be further included.

The first through-hole 16 that is not reused as the alignment connection hole 161 is the first connection hole 162.

Along the thickness direction Z of the display panel 100, among orthographic projection of the first through-holes 16 onto the plane of the light-exiting surface of the display panel 100, at least one first connection hole 162 is located between two alignment connection holes 161 along the direction of the plane of the light-exiting surface of the display panel 100.

In an example, an embodiment of the present disclosure further provides an optional implementation where the first conductive layer 14 and the second conductive layer 15 of the display panel 100 are connected to each other through the first through-hole 16. At least one first through-hole 16 is reused as the alignment connection hole 161, while the remaining first through-hole 16 not reused as alignment connection holes 161 is the first connection hole 162. The first connection hole 162 is used to establish the connection between the first conductive layer 14 and the second conductive layer 15, enabling the transmission of signals between the first conductive layer 14 and the second conductive layer 15 connected by the first connection holes 162, thereby facilitating related functions in the display panel 100. Furthermore, along the thickness direction Z of the display panel 100, among orthographic projections of the first through-holes 16 onto the plane of the light-exiting surface of the display panel 100, at least one first connection hole 162 is located between two alignment connection holes 161 along the direction of the plane of the light-exiting surface of the display panel 100. This arrangement helps to avoid clustering of the alignment connection holes 161 in a specific region, making the alignment connection holes 161 clearly distinguished from the surrounding first connection holes 162, thus achieving the effect of alignment usage.

FIG. 14 is another cross-sectional view taken along AA′ in FIG. 1 according to an embodiment of the present disclosure. Referring to FIG. 1, FIG. 3, and FIG. 14, in an implementation manner, the display panel 100 includes a light shielding member 50.

Along the thickness direction Z of the display panel 100, the light shielding member 50 is located at a side of the first conductive layer 14 away from the second conductive layer 15, and a side of the alignment connection hole 161 facing the light-exiting surface of the display panel 100 does not overlap with the light shielding member 50.

In an example, the display panel 100 includes the first conductive layer 14 and the second conductive layer 15. When the first conductive layer 14 and the second conductive layer 15 are connected to each other through the first through-hole 16, an embodiment of the present disclosure further provides an optional implementation where a light shielding member 50 is further provided in the display panel 100. The light shielding member 50 can be arranged at a side of the first conductive layer 14 away from the second conductive layer 15. The first conductive layer 14 is located at a side of the second conductive layer 15 facing the light-emitting element 13. Along the thickness direction Z of the display panel 100, a side of the alignment connection hole 161 facing the light-exiting surface of the display panel 100 may not overlap with the light shielding member 50. This prevents the light shielding member 50 from obstructing the alignment connection hole 161. In other words, the side of the alignment connection hole 161 facing the light-exiting surface of the display panel 100 is configured as a clearance region, allowing the alignment recognition device to easily recognize the alignment connection hole 161 arranged in the display panel 100. This improves the alignment effect during module assembly and enhances the assembly accuracy between modules.

Referring to FIG. 1 to FIG. 3, and FIG. 12, in an implementation manner, the display panel 100 includes at least two alignment connection holes 161.

The light-exiting surface of the display panel 100 is in an axisymmetric shape. The axisymmetric shape includes at least one first symmetry axis P, which is located in the plane of the light-exiting surface of the display panel 100. At least two alignment connection holes 161 are symmetrically arranged about the first symmetry axis P.

In an example, an embodiment of the present disclosure further provides an optional implementation where the display region 11 of the display panel 100 is in an axisymmetric shape, such as a circle or a rectangle. In this case, the display panel 100 can include an even number of alignment connection holes 161. These alignment connection holes 161 can be symmetrically arranged at both sides of at least one first symmetry axis P of the axisymmetric shape. For example, if the display region 11 of the display panel 100 is in a square shape, and there are only two alignment connection holes 161 in the display panel 100, the two alignment connection holes 161 can be arranged in any two corner regions of the square display region 11. By symmetrically placing the alignment connection holes 161 within the axisymmetric-shaped display region 11 of the display panel 100, it helps to increase the speed of recognizing the alignment connection holes 161, thus enhancing the alignment speed during module assembly.

Furthermore, for example, when the display region 11 of the display panel 100 is rectangular, at least two alignment connection holes 161 can be separately arranged in at least two corner regions of the display region 11 as needed, which facilitates increasing the speed of recognizing the alignment connection holes 161. For example, when the display region 11 of the display panel 100 is polygonal, at least two alignment connection holes 161 can also be separately arranged in at least two corner regions of the display region 11 as needed, which also helps to increase the speed of recognizing the alignment connection holes 161. It should be additionally noted that the present disclosure does not specifically limit the positions of the alignment connection holes 161 in the display panel 100, provided that a favorable alignment recognition effect can be achieved.

Furthermore, the alignment connection holes 161 can be evenly distributed in the display region 11 of the display panel 100 as needed. For example, the spacing and distribution density of the alignment connection holes 161 can be controlled to avoid clustering the alignment connection holes 161 in a specific region, which could affect the ultimate display effect in that region. This ensures the good display effect of the display panel 100.

Referring to FIG. 1 to FIG. 3 and FIG. 12, in an implementation manner, the display panel includes a display region 11 and a non-display region 12 at least partially surrounding the display region 11. The display region 11 includes a first display region 111 and a second display region 112 surrounding the first display region 111.

The alignment connection holes 161 are located within the second display region 112.

In an example, the display panel 100 can include a display region 11 and a non-display region 12 at least partially surrounding the display region 11. The display region 11 includes a first display region 111 and a second display region 112 surrounding the first display region 111. In other words, the second display region 112 is located between the first display region 111 and at least a portion of the non-display region 12. Since users primarily focus on the central display region 11 when using the display device, in an optional implementation provided by the present disclosure, all the alignment connection holes 161 are arranged within the second display region 112. That is, the alignment connection holes 161 are arranged at positions, within the display region 11, close to the non-display region 12. By positioning the alignment marks at an edge of the display region, it is more conducive to mitigating or avoiding any impact that the alignment connection holes 161 might have on the final display effect observed by the user in the display region 11.

Referring to FIG. 1 to FIG. 3, in an implementation manner, along the thickness direction Z of the display panel 100, the first through-hole 16 is formed by a recess from the first conductive layer 14 towards the second conductive layer 15.

In an example, when the display panel 100 includes the first conductive layer 14 and the second conductive layer 15, and the first conductive layer 14 and the second conductive layer 15 are connected to each other through the first through-hole 16, the first conductive layer 14 can be arranged at a side of the second conductive layer 15 facing the light-emitting element 13. Along the thickness direction Z of the display panel 100, the first through-hole 16 can be specifically formed by a recess from the first conductive layer 14 towards the second conductive layer 15. At least a portion of the first conductive layer 14 is directly indented to the surface of the second conductive layer 15 facing the first conductive layer 14, thereby achieving the connection between the first conductive layer 14 and the second conductive layer 15. In an implementation manner, each of the first conductive layer 14 and/or the second conductive layer 15 can be made of a metal material. The metal material has excellent reflective properties, which makes the formed alignment connection holes 161 more recognizable. This helps to increase the speed of recognizing the alignment connection holes 161.

It should be additionally noted that using the metal material to cover the alignment connection holes 161 serves the following two purposes. In an aspect, it facilitates the alignment function between module components by employing the special-shaped alignment connection holes 161. In another aspect, due to the excellent reflective properties of the metal material, the metal material reflect light towards different directions, making the alignment connection holes 161 being more pronounced and easier to be recognized.

Referring to FIG. 1 to FIG. 3, in an implementation manner, along the thickness direction Z of the display panel 100, the alignment connection hole 161 is cross-shaped.

In an example, in an optional implementation provided by the present disclosure, the alignment connection hole 161 is cross-shaped along the thickness direction Z of the display panel 100. However, the present disclosure is not limited thereto, provided that the shape of the alignment connection hole 161 of the first through-holes 16 is different from the shape of the first connection hole. As long as there is a difference between the shape of the alignment connection hole 161 and the shape of the first connection hole, the alignment connection hole 161 can be recognized. Certainly, a more significant difference between the shape of the alignment connection hole 161 and the shape of the first connection hole can better increase the speed of recognizing the alignment connection hole 161.

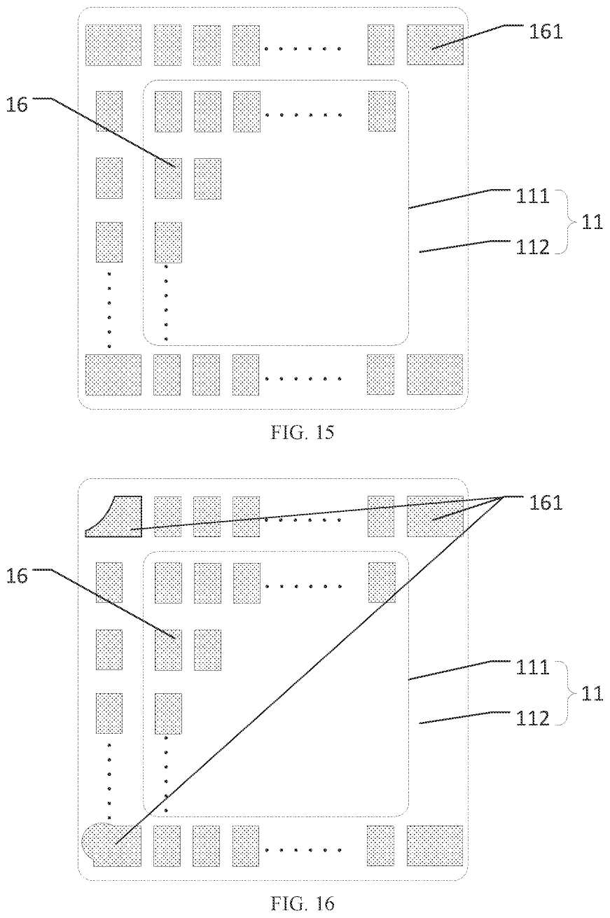

FIG. 15 is another top view of first through-holes according to an embodiment of the present disclosure; and FIG. 16 is another top view of first through-holes according to an embodiment of the present disclosure. Further referring to FIG. 15 and FIG. 16, it should be additionally noted that, along the thickness direction Z of the display panel 100, the alignment connection hole 161 can also be circular, rectangular, or trapezoidal, or in other irregular special shapes. As shown in FIG. 15, both the alignment connection hole 161 and the first connection hole can be rectangular. The alignment connection hole 161 and the first connection hole have a same dimension along a column direction, but different dimensions along a row direction. Such a configuration allows for a more even distribution of the through-holes while the alignment connection hole 161 can be clearly recognized. Additionally, this configuration also facilitates the electrical connection of structural components using the alignment connection holes 16, thereby improving both the alignment precision and the connection reliability and stability of the conductive material. As shown in FIG. 16, the alignment connection hole 161 can also be in a shape with a concave arc or convex arc. In other words, the alignment mark can be in a shape with curved edges, or the alignment mark can take the form of a convex polygon. That is, some edges can be straight while others can be curved. In other words, the projected pattern of the through-hole forms a polygon, and the angle between two adjacent edges is not less than 90 degrees. This configuration facilitates the electrical connection between structural components using the alignment connection holes 16, and improves both the alignment precision and the connection reliability and stability of the conductive materials.

It should be additionally noted that, the present disclosure does not require all the alignment connection holes 161 in the display panel 100 to have a same shape. Instead, different shapes can be selected for the alignment connection holes 161 as needed.

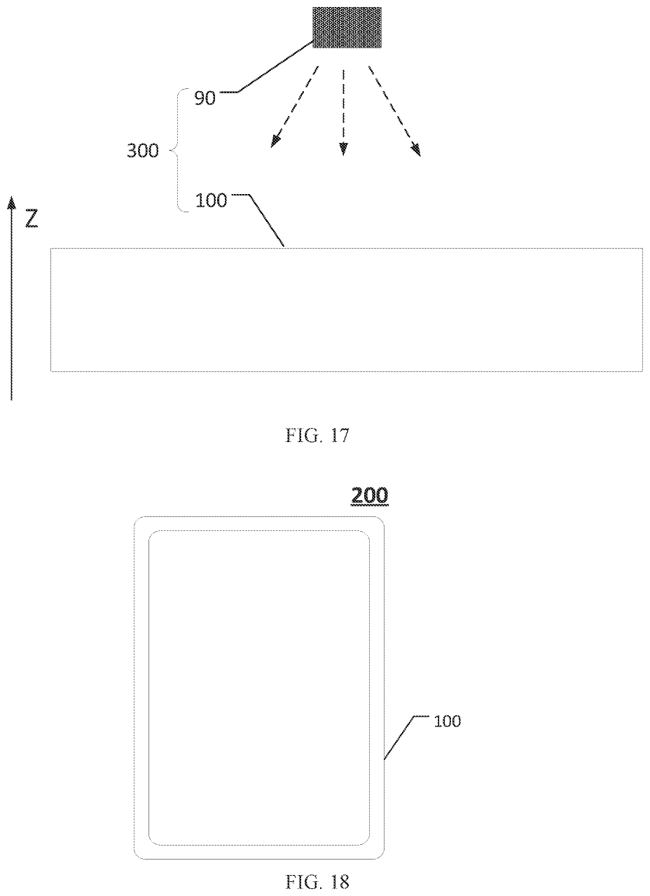

FIG. 17 is a schematic diagram of a detection device of a display panel according to an embodiment of the present disclosure. Referring to FIG. 1 to FIG. 14 and FIG. 17, based on the same inventive conception, an embodiment of the present disclosure further provides a detection device 300 of a display panel. The detection device is configured to detect a display panel 100, where the display panel 100 is any display panel 100 provided by the present disclosure.

The detection device further includes a recognition device 90.

The recognition device 90 is located at a side of a light-exiting surface of the display panel 100.

The recognition device 90 is configured to photograph the display panel 100 to recognize an alignment connection hole 161 in the display panel 100.

In an example, an embodiment of the present disclosure further provides a detection device for a display panel 100. The detection device can be configured to recognize the alignment connection hole 161 in the display panel 100. A recognition device 90 can be disposed at the side of the light-exiting surface of the display panel 100. The recognition device 90 is used to photograph the display panel 100. Since the alignment connection hole 161 and the remaining first connection holes have different shapes on the light-exiting surface of the display panel 100, the alignment connection hole 161 in the display panel 100 can be easily recognized using the captured photograph. The recognition device 90, for example, can be a charge coupled device (CCD).

When the display panel 100 needs to be aligned and module assembled with a corresponding substrate (not shown), the corresponding substrate may be provided with alignment members in one-to-one correspondence with the alignment connection holes 161. The alignment members can be tightly fitted with the corresponding alignment connection holes 161 after alignment, to achieve module assembly between the display panel 100 and the corresponding substrate.

FIG. 18 is a schematic diagram of a display device according to an embodiment of the present disclosure. Referring to FIG. 1 to FIG. 14 and FIG. 18, based on the same inventive conception, an embodiment of the present disclosure further provides a display device 200 that includes a display panel 100. The display panel is any display panel 100 provided by the present disclosure.

It should be noted that for the embodiments of the display device provided by the present disclosure, reference can be made to the embodiments of the display panel described above, and repeated parts are not described again herein. The display device provided by the present disclosure may be any product or component with a display function, such as a mobile phone, a tablet computer, a television, a display, a notebook computer, a vehicle display screen, or a navigator.

As can be learned from the foregoing embodiments, the display panel, the detection device therefor, and the display device that are provided by the present disclosure achieve at least the following beneficial effects.

The present disclosure provides a display panel, a detection device therefor, and a display device. The display panel includes an array layer and a light-emitting element located at one side of the array layer. Along a thickness direction of the display panel, the array layer includes a first conductive layer and a second conductive layer that are insulated from each other. The first conductive layer and the second conductive layer are connected to each other through at least one first through-hole. At least one first through-hole can be reused as an alignment connection hole; and/or, along the thickness direction of the display panel, orthographic projections of at least two first through-holes onto a plane of a light-exiting surface of the display panel have different shapes. In this way, at least one first through-hole originally existing in the array layer is reused as the alignment connection hole, thereby not increasing the manufacturing process of the display panel. Besides, the alignment mark (alignment connection hole) is arranged in a display region of the display panel, thereby not enlarging an area of the display region of the display panel or reducing the quantity of pixel units for the arrangement of the alignment connection hole, thus avoiding a decrease in the PPI of the display panel. Moreover, the alignment mark helps to improve the alignment effect during module assembly and enhance the assembly precision between modules.

Although some specific embodiments of the present disclosure have been explained in detail through examples, those skilled in the art should understand that the above examples are only for illustration and not intended to limit the scope of the present disclosure. Those skilled in the art should understand that modifications can be made to the aforementioned embodiments without departing from the scope and spirit of the present disclosure. The scope of the present disclosure is defined by the appended claims.

What is claimed is:

1. A display panel, comprising:
an array layer, wherein, along a thickness direction of the display panel, the array layer comprises at least a first conductive layer and a second conductive layer, and at least an insulating layer is located between the first conductive layer and the second conductive layer;
a light-emitting element located at a side of the array layer facing a light-exiting surface of the display panel; and
at least one first through-hole,
wherein the first conductive layer and the second conductive layer are connected to each other through the at least one first through-hole, and at least one of the at least one first through-hole is reused as an alignment connection hole; and/or, along the thickness direction of the display panel, orthographic projections of at least two of the at least one first through-hole onto a plane of the light-exiting surface of the display panel have different shapes.

2. The display panel according to claim 1, wherein the array layer further comprises a connection electrode electrically connected to the light-emitting element, and the connection electrode reuses the first conductive layer; and
wherein the first conductive layer is located at a side of the second conductive layer facing the light-emitting element.

3. The display panel according to claim 1, wherein the array layer further comprises a capacitor, and one electrode plate of the capacitor reuses the first conductive layer; and
wherein the first conductive layer is located at a side of the second conductive layer facing the light-emitting element.

4. The display panel according to claim 1, wherein the array layer further comprises a first transistor, and a source-drain layer of the first transistor reuses the first conductive layer; and
wherein the first conductive layer is located at a side of the second conductive layer facing the light-emitting element.

5. The display panel according to claim 1, wherein the array layer further comprises capacitors;
wherein, along the thickness direction of the display panel, at least one of the capacitors comprises a first electrode plate and a second electrode plate that are opposite to each other, and the first electrode plate is located at a side of the second electrode plate facing the light-emitting element;
wherein the first electrode plate reuses the first conductive layer; and
wherein the first conductive layer is located at a side of the second conductive layer facing the light-emitting element.

6. The display panel according to claim 5, wherein the array layer further comprises a first active layer, and, along the thickness direction of the display panel, the first active layer is located at a side of the second conductive layer away from the first conductive layer; and
wherein the array layer further comprises a second transistor, wherein a source-drain layer of the second transistor is arranged in the first conductive layer, an active layer of the second transistor is arranged in the first active layer, and the second electrode plate is arranged in the second conductive layer.

7. The display panel according to claim 5, wherein the array layer further comprises a capacitor intermediate layer located between the first electrode plate and the second electrode plate;
wherein, along the thickness direction of the display panel, the capacitor intermediate layer at least partially overlaps with the first electrode plate, and the capacitor intermediate layer at least partially overlaps with the second electrode plate; and
wherein the display panel further comprises at least one second through-hole, the first electrode plate and the capacitor intermediate layer are connected to each other through the at least one second through-hole, and at least one of the at least one second through-hole is reused as the alignment connection hole.

8. The display panel according to claim 1, wherein the array layer further comprises a third conductive layer, and along the thickness direction of the display panel, the first conductive layer is located at a side of the second conductive layer facing the light-emitting element, and the third conductive layer is located at a side of the first conductive layer away from the second conductive layer; and
wherein the display panel further comprises at least one second through-hole, wherein the first conductive layer and the third conductive layer are connected to each other through the at least one second through-hole, and at least one of the at least one second through-hole is reused as the alignment connection hole.

9. The display panel according to claim 7, wherein along the thickness direction of the display panel, an orthographic projection of at least one of the at least one first through-hole onto the plane of the light-exiting surface of the display panel and an orthographic projection of at least one of the at least one second through-hole onto the plane of the light-exiting surface of the display panel have a same shape.

10. The display panel according to claim 1, wherein the array layer further comprises at least one second through-hole, and along the thickness direction of the display panel, the at least one second through-hole is located at a side of the at least one first through-hole away from the light-emitting element; and
wherein, along the thickness direction of the display panel, the at least one second through-hole does not overlap with the alignment connection hole.

11. The display panel according to claim 1, wherein the light-emitting element comprises at least a first color light-emitting element;
wherein the array layer further comprises a first connection electrode electrically connected to the first color light-emitting element, and the first connection electrode reuses the first conductive layer; and/or
wherein the array layer further comprises a first capacitor corresponding to the first color light-emitting element, and one electrode plate of the first capacitor reuses the first conductive layer; and/or
wherein the array layer further comprises a third transistor corresponding to the first color light-emitting element, and a source-drain layer of the third transistor reuses the first conductive layer;
wherein the first color light-emitting element does not comprise a green color light-emitting element; and
wherein the first conductive layer is located at a side of the second conductive layer facing the light-emitting element.

12. The display panel according to claim 1, further comprising:
at least one first connection hole;
wherein the first through-hole of the at least one first through-hole that is not reused as the alignment connection hole is the first connection hole; and
wherein, along the thickness direction of the display panel, for orthographic projections of the at least one first through-hole onto the plane of the light-exiting surface of the display panel, at least one first connection hole is located between two alignment connection holes along the direction of the plane of the light-exiting surface of the display panel.

13. The display panel according to claim 1, wherein the display panel comprises a light shielding member; and
wherein, along the thickness direction of the display panel, the light shielding member is located at a side of the first conductive layer away from the second conductive layer, and a side of the alignment connection hole facing the light-exiting surface of the display panel does not overlap with the light shielding member.

14. The display panel according to claim 1, further comprising at least two alignment connection holes, wherein the light-exiting surface of the display panel is in an axisymmetric shape, wherein the axisymmetric shape comprises at least one first symmetry axis located in the plane of the light-exiting surface of the display panel, and the at least two alignment connection holes are symmetrically arranged about the first symmetry axis.

15. The display panel according to claim 1, further comprising: a display region and a non-display region at least partially surrounding the display region, wherein the display region comprises a first display region and a second display region surrounding the first display region, and the alignment connection hole is located within the second display region.

16. The display panel according to claim 1, wherein, along the thickness direction of the display panel, the at least one first through-hole is formed by a recess from the first conductive layer towards the second conductive layer.

17. The display panel according to claim 1, wherein at least one of the second conductive layer or the first conductive layer comprises a metal material.

18. The display panel according to claim 1, wherein, along the thickness direction of the display panel, the alignment connection hole is cross-shaped.

19. A display device, comprising a display panel comprising:
an array layer, wherein, along a thickness direction of the display panel, the array layer comprises at least a first conductive layer and a second conductive layer, and at least an insulating layer is located between the first conductive layer and the second conductive layer;
a light-emitting element located at a side of the array layer facing a light-exiting surface of the display panel; and
at least one first through-hole,
wherein the first conductive layer and the second conductive layer are connected to each other through the at least one first through-hole, and at least one of the at least one first through-hole is reused as an alignment connection hole; and/or, along the thickness direction of the display panel, orthographic projections of at least two of the at least one first through-hole onto a plane of the light-exiting surface of the display panel have different shapes.

20. A detection device for a display panel, wherein the detection device comprises a recognition device, and the display panel comprises:
an array layer, wherein, along a thickness direction of the display panel, the array layer comprises at least a first conductive layer and a second conductive layer, and at least an insulating layer is located between the first conductive layer and the second conductive layer;
a light-emitting element located at a side of the array layer facing a light-exiting surface of the display panel; and
at least one first through-hole,
wherein the first conductive layer and the second conductive layer are connected to each other through the at least one first through-hole, and at least one of the at least one first through-hole is reused as an alignment connection hole; and/or, along the thickness direction of the display panel, orthographic projections of at least two of the at least one first through-hole onto a plane of the light-exiting surface of the display panel have different shapes, and
wherein the recognition device is located at a side of the light-exiting surface of the display panel, and the recognition device is configured to photograph the display panel to recognize the alignment connection hole in the display panel.
